(19) United States
(12) Patent Application Publication
(10) Pub. No.: US 2019/0104718 A1
(43) Pub. Date: Apr. 11, 2019

(54) ENTRY BARRIER

(71) Applicant: Efran Cano, Phoenix, AZ (US)

(72) Inventor: Efran Cano, Phoenix, AZ (US)

(21) Appl. No.: 15/728,258

(22) Filed: Oct. 9, 2017

(51) Int. Cl. A01M 1/24; A01M 1/22; A01M 19/00

(52) U.S. Cl. CPC A01M 1/24; H05K 1/181; A01M 19/00; A01M 1/223

(57) ABSTRACT

An entry barrier for a doorway includes a first strip, mechanically coupled to a jamb and a threshold around a strike plate. A second strip is mechanically coupled to the jamb and the threshold around the strike plate and parallel to the first strip. A printed circuit board in a power source unit is electrically coupled to the first strip and the second strip. The printed circuit board directs electrical power from the power source unit to the first strip and the second strip such that a pest contacting the first strip or the second strip is electrocuted.

### BACKGROUND

The embodiments herein relate generally to construction of building and civil engineering.

Prior to embodiments of the disclosed invention, pests such as insects, could enter a structure beneath a door. Pest control chemicals were bad for health of adults, children, and pets. Embodiments of the disclosed invention solve this problem.

### SUMMARY

An entry barrier for a doorway includes a first strip, mechanically coupled to a jamb and a threshold around a strike plate. A second strip is mechanically coupled to the jamb and the threshold around the strike plate and parallel to the first strip. A printed circuit board in a power source unit is electrically coupled to the first strip and the second strip. The printed circuit board directs electrical power from the power source unit to the first strip and the second strip such that a pest contacting the first strip or the second strip is electrocuted.

### BRIEF DESCRIPTION OF THE FIGURES

The detailed description of some embodiments of the invention is made below with reference to the accompanying figures, wherein like numerals represent corresponding parts of the figures.

FIG. 1 shows a perspective view of one embodiment of the present invention shown in use in an open position;

FIG. 2 shows a perspective view of one embodiment of the present invention shown in use in a closed position;

FIG. 3 shows a section view of one embodiment of the present invention taken along line 3-3 in FIG. 2 with some parts shown schematically;

FIG. 4A shows a section view of one embodiment of the present invention taken along line 4A-4A in FIG. 3;

FIG. 4B shows a section view of one embodiment of the present invention taken along line 4B-4B in FIG. 3; and

FIG. 5 shows a section view of one embodiment of the present invention taken along line 5-5 in FIG. 2.

### DETAILED DESCRIPTION OF CERTAIN EMBODIMENTS

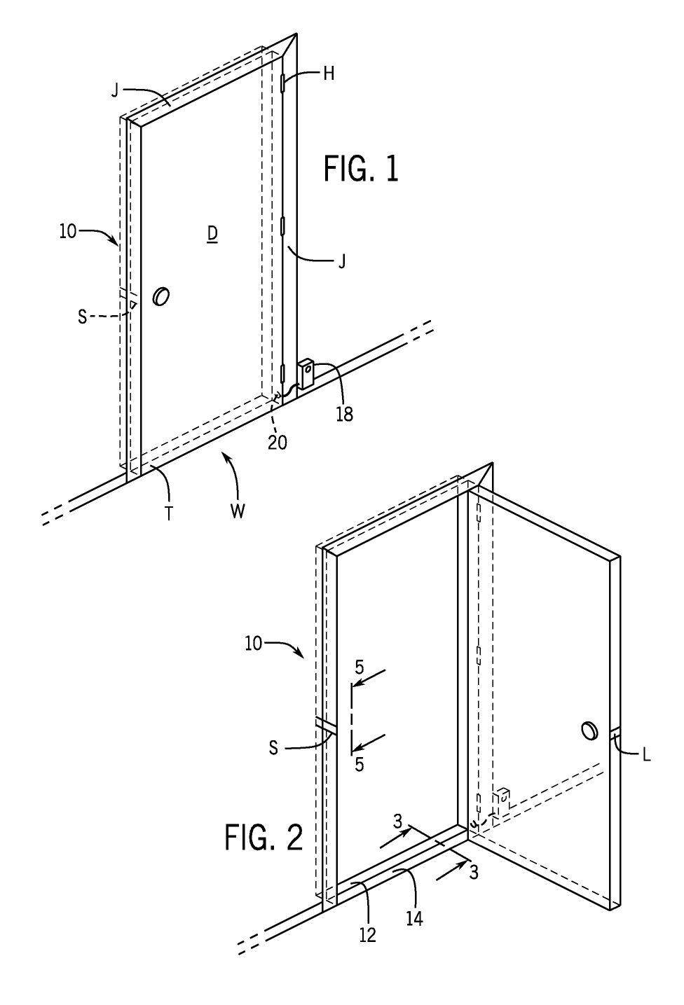

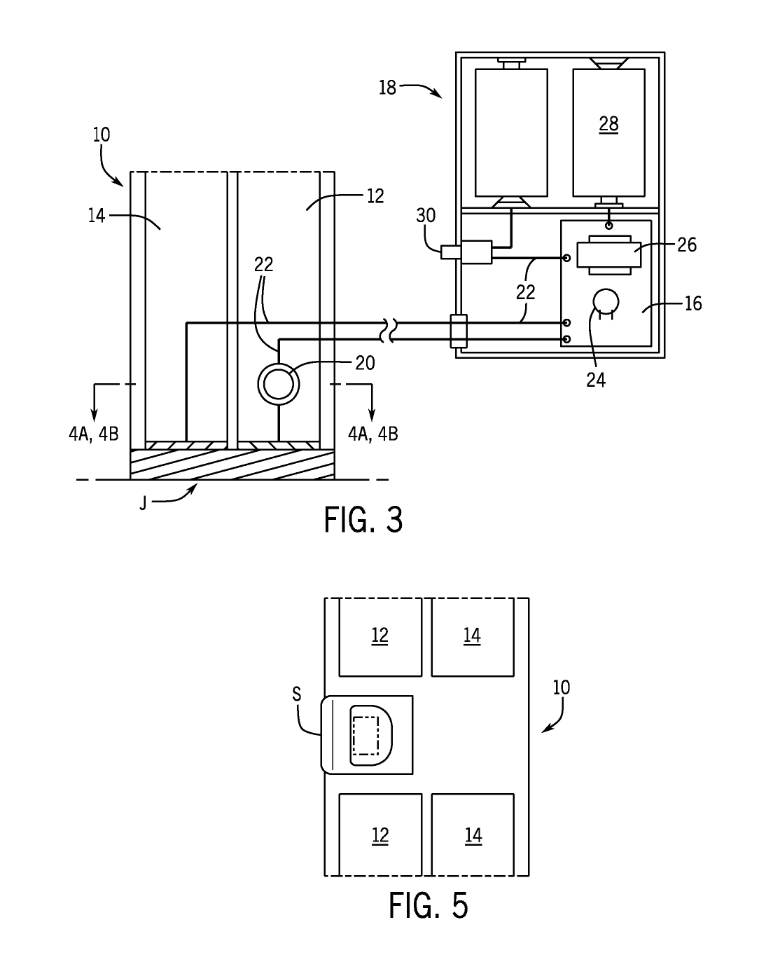

By way of example, and referring to FIGS. 1-5, one embodiment of an entry barrier 10 is arranged in a doorway W. The doorway W further comprises a threshold T. The threshold T is joined to a jamb J. The jamb J is attached to a door D with a plurality of hinges H. The jam J is further attached to a strike plate S which is adapted to accommodate a lockset L in the door D.

The entry barrier 10 further comprises a first strip 12 and a second strip 14 which travel along the jamb J and the threshold T but stop on either side of the strike plate S. The first strip 12 and the second strip 14 can be made of any electrically conductive material, but copper has been shown to be effective.

The first strip 12 is electrically coupled to a printed circuit board 16 in a power source unit 18. The second strip 14 is electrically coupled to the printed circuit board 16 with a tactile switch 20. In some embodiments, these connections can be made with at least one electrical wire 22.

The printed circuit board 16 is mechanically and electrically coupled to a capacitor 24 and a transformer 26. The printed circuit board 16 is electrically coupled to at least one battery 28 with at least one switch 30.

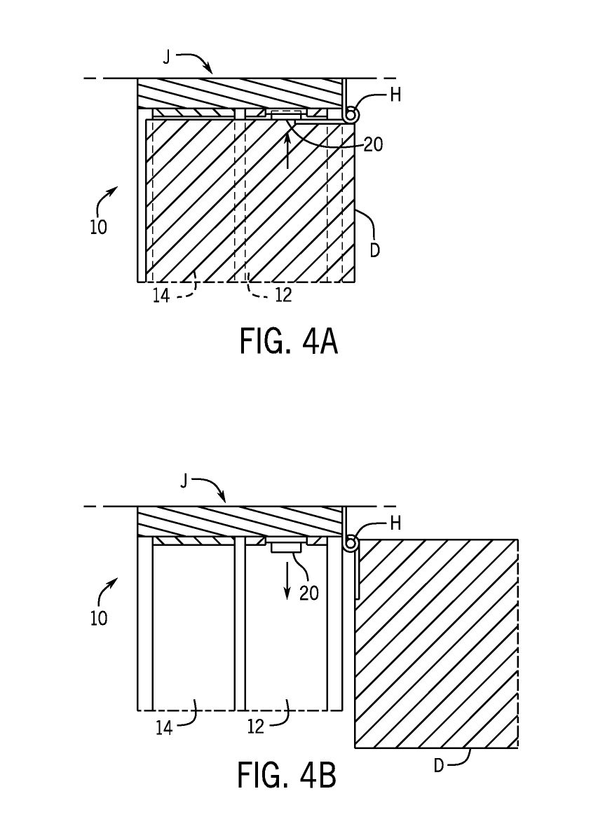

Turning to FIG. 4A, the printed circuit board 16 is programmed with instructions to determine if the door D is sufficiently proximate the jamb J such that the tactile switch 20 on the jamb J is compressed by the door D. Then, the printed circuit board 16 permits electrical current to flow from the at least one battery 28 through the first strip 12 and the second strip 14.

Turning to FIG. 4B, the printed circuit board 16 is programmed with instructions to determine if the door D is sufficiently distant the jamb J such that the tactile switch 20 on the jamb J is extended toward the door D. Then, the printed circuit board 16 prevents electrical current from flowing from the at least one battery 28 through the first strip 12 and the second strip 14.

As used in this application, the term “a” or “an” means “at least one” or “one or more.”

As used in this application, the term “about” or “approximately” refers to a range of values within plus or minus 10% of the specified number.

As used in this application, the term “substantially” means that the actual value is within about 10% of the actual desired value, particularly within about 5% of the actual desired value and especially within about 1% of the actual desired value of any variable, element or limit set forth herein.

All references throughout this application, for example patent documents including issued or granted patents or equivalents, patent application publications, and non-patent literature documents or other source material, are hereby incorporated by reference herein in their entireties, as though individually incorporated by reference, to the extent each reference is at least partially not inconsistent with the disclosure in the present application (for example, a reference that is partially inconsistent is incorporated by reference except for the partially inconsistent portion of the reference).

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

Any element in a claim that does not explicitly state “means for” performing a specified function, or “step for” performing a specified function, is not to be interpreted as a “means” or “step” clause as specified in 35 U.S.C. § 112, ¶6. In particular, any use of “step of” in the claims is not intended to invoke the provision of 35 U.S.C. § 112, ¶6.

Persons of ordinary skill in the art may appreciate that numerous design configurations may be possible to enjoy the functional benefits of the inventive systems. Thus, given the wide variety of configurations and arrangements of embodiments of the present invention the scope of the invention is reflected by the breadth of the claims below rather than narrowed by the embodiments described above.

What is claimed is:

1. An entry barrier for a doorway; the entry barrier comprising
a first strip, mechanically coupled to a jamb and a threshold around a strike plate;
a second strip, mechanically coupled to the jamb and the threshold around the strike plate and parallel to the first strip;
a printed circuit board in a power source unit, electrically coupled to the first strip and the second strip;
wherein the printed circuit board directs electrical power from the power source unit to the first strip and the second strip such that a pest contacting the first strip or the second strip is electrocuted.

2. The entry barrier of claim 1, further comprising a tactile switch mechanically coupled to the jamb and electrically coupled to the second strip and the printed circuit board.

3. The entry barrier of claim 2, further comprising at least one battery, electrically coupled to the printed circuit board with at least one switch.

4. The entry barrier of claim 3 wherein the printed circuit board is programmed with instructions to:
determine that the door is sufficiently proximate the jamb that the tactile switch on the jamb is compressed by the door; and
permit electrical current to flow from the at least one battery through the first strip and the second strip.

5. The entry barrier of claim 3 wherein the printed circuit board is programmed with instructions to:
determine that the door is sufficiently distant the jamb that the tactile switch on the jamb extends toward the door; and
stop electrical current from flowing from the at least one battery through the first strip and the second strip.
